(19) United States
(12) Patent Application Publication
(10) Pub. No.: US 2002/0033717 A1
(43) Pub. Date: Mar. 21, 2002

(54) Titanium alloy

(76) Inventor: Aritsune Matsuo, Hamamatsu-city (JP)

Correspondence Address: NIXON & VANDERHYE P.C., 8th Floor, 1100 North Glebe Rd., Arlington, VA, 22201-4714, US

(21) Appl. No.: 09/871,969

(22) Filed: Jun. 4, 2001

(30) Foreign Application Priority Data
Jun. 5, 2000 (JP) 2000-167642

(51) Int. Cl. H03K 5/00

(52) U.S. Cl. 327/94

(57) ABSTRACT

A titanium alloy having a composition represented by the chemical formula Ti₁₀₀₋ₓM1ₓ, wherein M1 is at least one element selected from the group consisting of Zr, Hf, Nb, Ta and V, x is atomic % or the sum of atomic % of the element(s), and x is 20 to 80 atomic %; and a titanium alloy having a composition represented by the chemical formula Ti_{100-x-y}M1ₓM2_{y}, wherein M1 is at least one element selected from the group consisting of Zr, Hf, Nb, Ta and V, x is atomic % or the sum of atomic % of the element(s), M2 is at least one element selected from the group consisting of Al, Sn, Mo, Cr, Ag, Au, Pd, Pt, Ni, Co, Fe, Si, Mn, B, Mm, Sc, Y, La, Ce, Pr, Nd and Sm, y is atomic % or the sum of atomic % of the element(s), and the sum of x and y is 20 to 80 atomic %.

### BACKGROUND OF THE INVENTION

1. Field of the Invention

The present invention relates to titanium alloys and titanium alloy materials or materials made of the titanium alloys, and more particularly to titanium alloys which are well workable in a cold state, well hardened by working and have low modulus of elasticity or low Young's modulus, and titanium alloy materials or materials made of the titanium alloys.

2. Description of the Prior Art

For use in accessories, spectacle frames, daily necessaries, office supplies, medical instruments and the like, it is desirable that titanium alloys are well worked during processing in a cold state such as rolling, wire-drawing, press-forming, or swaging. Additionally, for materials thus formed of the titanium alloys into predetermined shapes by such cold working, it is required that they have high strength, high hardness, high resistance for wearing, and high flexibility.

To date, with respect to their constitutions, three kinds of titanium alloys have been known, that is, pure titanium metal or α-type titanium alloys with less than 10 weight % Zr and/or Al, (α+β)-type titanium alloys with several weight % Al and/or V, and β-type titanium alloys with more than 20 weight % V and/or Nb.

Although the pure titanium metal and α-type titanium alloys are well workable in a cold state, they do not become so strong or hard even after cold working with a reduction ratio of sectional area or a rolling rate of 90% that the hardness thereof reaches only Hv 250 to 270 and they have modulus of elasticity of 100 to 105 GPa.

The (α+β)-type titanium alloys are not easily worked in a cold state especially with a reduction ratio of sectional area more than 50% such that cracks may frequently occur during cold working. Although their hardness may become as high as Hv 300 to 350 by cold working with a reduction ratio of sectional area of 50 to 60%, they have modulus of elasticity of 100 to 110 GPa, resulting in low flexibility.

The β-type titanium alloys generally are more workable than the (α+β)-type titanium alloys and can be worked with the reduction ratio of sectional area of 90% such that their hardness may become as high as Hv 280 to 330 by cold working, though they are less strong than the (α+β)-type titanium alloys. However, they have modulus of elasticity of 80 to 90 GPa, resulting in higher flexibility.

Although the strength of the β-type titanium alloys can be increased by aging heat treatment, the process is complicated and increases their brittleness, resulting in preventing industrialization of the process.

Titanium alloys are useful materials for watches, spectacle frames, office supplies and the like, and it has long been desired to improve workability in a cold state, strength or hardness, and flexibility thereof for such uses.

In detail, improvement in the following properties is desired for titanium alloys:

(a) workability in a cold state with a reduction ratio of sectional area more than 90%;

(b) tensile strength of 1000 to 1200 MPa or hardness of Hv 350 to 400 to be attained by cold working without heat treatment;

(c) flexibility with modulus of elasticity less than 80 GPa; and

(d) density not to be largely increased from that of pure titanium metal.

### SUMMARY OF THE INVENTION

It is, therefore, a primary object of the present invention to provide titanium alloys satisfying the desires described above by the improvement of the (α+β)-type titanium alloys.

In accordance with a first aspect of the present invention, there is provided a titanium alloy having a composition represented by the chemical formula Ti_{100 -x}M1ₓ, wherein M1 is at least one element selected from the group consisting of Zr, Hf, Nb, Ta and V, x is atomic % or the sum of atomic % of the element(s), and x is 20 to 80 atomic %.

In practice, in the titanium alloy described above, x may be 20 to 50 atomic %, the density thereof may be equal to or less than 1.5 times that of pure titanium metal, preferably equal to or less than 1.2 times, and the tensile strength before cold working may be defined to be 500 to 800 MPa.

Further, in the first aspect of the present invention, there is provided a titanium alloy material obtained by cold working of the titanium alloy described above. In this case, the reduction ratio of sectional area during the cold working preferably may be defined to be 50 to 95%, the titanium alloy may be treated by aging heat treatment after the cold working, and the temperature of the aging heat treatment preferably may be defined to be 300 to 800° C.

In accordance with a second aspect of the present invention, there is provided a titanium alloy having a composition represented by the chemical formula Ti_{100-x-y}M1ₓM2_{y}, wherein M1 is at least one element selected from the group consisting of Zr, Hf, Nb, Ta and V, x is atomic % or the sum of atomic % of the element(s), M2 is at least one element selected from the group consisting of Al, Sn, Mo, Cr, Ag, Au, Pd, Pt, Ni, Co, Fe, Si, Mn, B, Mm, Sc, Y, La, Ce, Pr, Nd and Sm, y is atomic % or the sum of atomic % of the element(s), and the sum of x and y is 20 to 80 atomic %.

In practice, in the titanium alloy described above, y may be 0.1 to 10 atomic %, preferably 1 to 5 atomic %, the sum of x and y may be 20 to 50 atomic %, the density of the titanium alloy may be equal to or less than 1.5 times that of pure titanium metal, preferably equal to or less than 1.2 times, and the tensile strength before cold working may be defined to be 500 to 800 MPa.

Further, in the same manner as the first aspect of the present invention, the second aspect of the present invention also provides titanium alloy materials of higher strength by cold working and aging heat treatment of the titanium alloys described above.

Reasons for the selection of elements constituting the titanium alloys in accordance with the present invention and the limitation of chemical compositions thereof will be described.

Firstly, generally speaking, the titanium alloys as component materials are desired to have a small density for every use. Secondly, before cold working, the titanium alloys are required to have adequately low hardness or low tensile strength of 500 to 800 MPa for smooth processing. Thirdly, as explained in detail hereinafter, the titanium alloys should be constituted of a homogeneous mixture of α-phase and β-phase and, after cold worked hard, amorphous layers should be formed at the grain boundaries between α-phase and β-phase, where atoms are randomly arranged.

With such a constitution, the titanium alloys can be worked hard in a cold state continuously without annealing to attain high hardness but to retain low modulus of elasticity.

The inventor has investigated many kinds of titanium alloys to select elements constituting the titanium alloys and to determine chemical compositions thereof in order to achieve the objects of the present invention, resulting in the elements and chemical compositions as claimed in claims described hereinafter.

In the titanium alloys in accordance with the present invention, a phenomenon called work hardening is important. Generally speaking, work hardening is a phenomenon occur during plastic working of metals or alloys below their recrystallization temperature, wherein the hardness or tensile strength thereof is increased according to an increase of work rate, resulting in a rapid increase of force to be applied for the working. This phenomenon is caused by increase of the number of dislocations in crystals to make movement of atoms difficult. In the titanium alloys in accordance with the present invention, as described above, after cold worked hard, amorphous layers are formed at the grain boundaries between α-phase and β-phase, where atoms are randomly arranged. Due to such a constitution different from usual crystalline structures is caused unique plastic deformation by cooperative movement of the amorphous layers in place of usual plastic deformation. As a result, the present titanium alloys have such remarkable characteristics as good workability in a cold state, good hardenability and large flexibility.

### BRIEF DESCRIPTION OF THE DRAWINGS

Other objects, features and advantages of the present invention will be more readily appreciated from the following detailed description of preferred embodiments thereof when taken together with the accompanying drawings, in which:

FIG. 1 illustrates the relationship between the reduction ratio of sectional area (%) in cold working and the tensile strength (MPa) for Example No. 16; and

FIG. 2 illustrates the relationship between the reduction ratio of sectional area (%) in cold working and the tensile strength (MPa) for Example No. 17.

### DESCRIPTION OF THE PREFERRED EMBODIMENTS

Hereinafter, embodiments of titanium alloys and titanium alloy materials in accordance with the present invention will be described in detail, wherein M1 is at least one element selected from the group consisting of Zr, Nb, Ta and V, and M2 is Al.

An amount of pure metals mixed according to a predetermined chemical composition was melted in a non-oxidizing atmosphere or, in this case, in vacuum by an arc furnace and cast into a water-cooled metallic mold to obtain an ingot of 10 mm in thickness. The ingot was retained in vacuum at 1100° C. for 24 hours for homogenization and cooled rapidly at a speed more than 5° C./sec. Then, the ingot was cold-rolled to obtain a specimen of 1.0 mm in thickness with the reduction ratio of sectional area of 90%. Specimens thus provided include Examples Nos. 1 to 19.

In Table 1 are shown characteristics of the nineteen examples such as chemical composition in atomic %, density, mechanical properties after cold working with the reduction ratio of sectional area of 90% including tensile strength (MPa), hardness Hv (load 500 g), modulus of elasticity (GPa), and corresponding claims in their chemical compositions (corresponding figures).

As is clearly seen from the table, the density of the titanium alloys each is less than 1.5 times that of pure titanium metal, that is, 4.5, and mostly less than 1.2 times. This means that the density of the titanium alloys each in the table is not largely increased from that of pure titanium metal. Although it is not shown in the table, before cold working, all samples listed here had the low tensile strength of 500 to 800 MPa to be well workable in a cold state.

In all examples, any crack was not detected after cold working even with the reduction ratio of sectional area of 90%. The tensile strength after cold working was as high as 1040 to 1260 MPa and the hardness Hv also was as high as 350 to 420. The modulus of elasticity, however, was less than about 80 GPa to provide large flexibility.

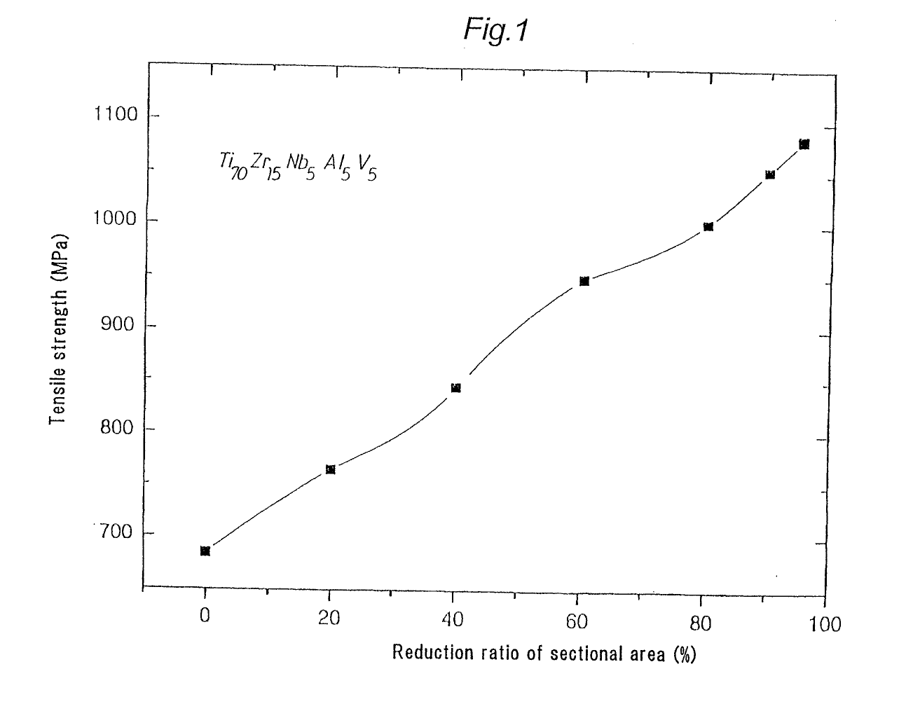

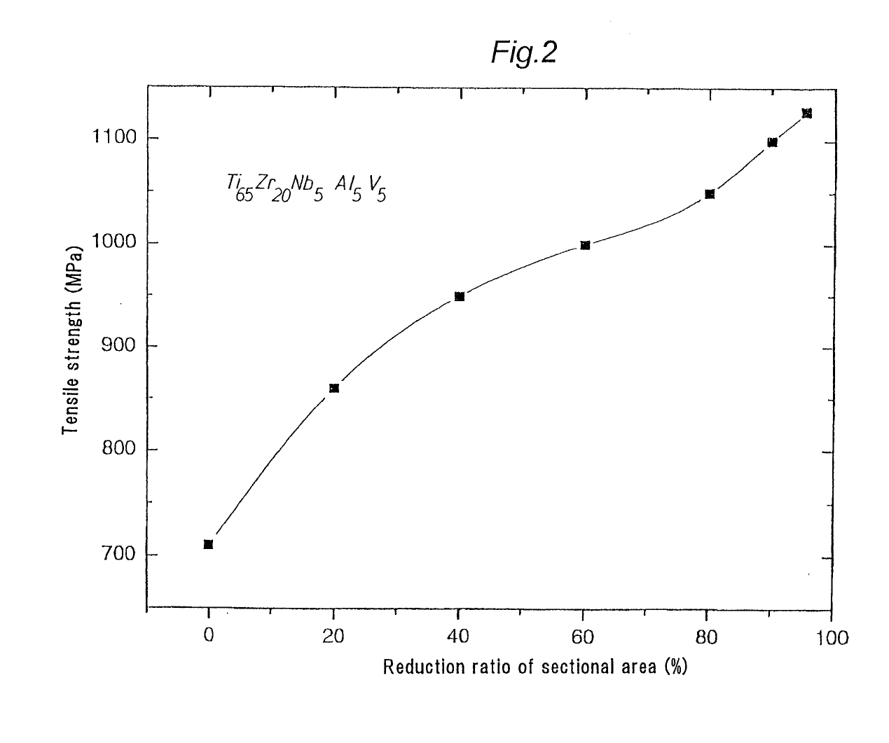

The attached drawings illustrate relationships between the reduction ratio of sectional area (%) in cold working and the tensile strength (MPa), FIG. 1 for Example No. 16 and FIG. 2 for Example No. 17, respectively. As is understood from the figures, each example has low tensile strength of about 700 MPa before cold working and high strength of about 1100 MPa after cold working, being well workable even with a reduction ratio of sectional area of 95%.

Some examples of aging heat treatment of the titanium alloys in accordance with the present invention will be described. In Examples Nos. 11 and 16, the titanium alloys were treated by aging heat treatment at 400° C. for 5 hours after cold working with the reduction ratio of sectional area of 90%, resulting in increase of the tensile strength from 1250 to 1600 MPa and from 1060 to 1400 MPa, that is, about 30%, respectively. Thus, the tensile strength and hardness of the titanium alloys can be increased by aging heat treatment after cold working. Temperatures of the aging heat treatment are determined in the range from 300 to 800° C. depending on the kind of the titanium alloys and their use.

In other embodiments, M1 was at least one element selected from a group including Hf in addition to Zr, Nb, Ta and V, and M2 was at least one element selected from a group including Sn, Mo, Cr, Ag, Au, Pd, Pt, Ni, Co, Fe, Si, Mn, B, Mm, Sc, Y, La, Ce, Pr, Nd and Sm in addition to Al. By these embodiments, the object of the present invention was also achieved.

Although the titanium alloys are formed into predetermined shapes by cold working as described above, they can be formed by press-forming after having been pulverized.

TABLE 1

| | Chemical | | | | | | Mechanical Properties | | | |
|---|---|---|---|---|---|---|---|---|---|---|
| | Composition | | | | | | Tensile | Hard- | Modulus of | Corresponding |
| Example | (atomic %) | | | | | | Strength | ness | Elasticity | Claim |
| No. | Zr | Nb | Ta | V | Al | Density | (MPa) | (Hv) | (GPa) | (figure) |
| 1 | 10 | 5 | | 5 | | 4.9 | 1050 | 350 | 75 | 2 |
| 2 | 20 | 5 | | 5 | | 5.2 | 1050 | 350 | 62 | 2 |
| 3 | 20 | 10 | 10 | | | 6.6 | 1050 | 410 | 55 | 2 |
| 4 | 25 | 10 | 10 | | | 6.6 | 1040 | 400 | 58 | 2 |
| 5 | 30 | 10 | 10 | | | 6.7 | 1120 | 400 | 56 | 2 |
| 6 | 30 | 10 | | | | 5.6 | 1150 | 400 | 60 | 2 |
| 7 | 35 | 5 | | | | 5.5 | 1150 | 400 | 63 | 2 |
| 8 | 15 | 5 | | 5 | 1 | 5.0 | 1050 | 350 | 62 | 12, 13 |
| 9 | 15 | | | 5 | 10 | 4.7 | 1060 | 360 | 81 | 11, 13 |
| 10 | 15 | | | 15 | 8 | 5.0 | 1260 | 410 | 63 | 11, 13 |
| 11 | 15 | 5 | | 10 | 8 | 5.2 | 1250 | 420 | 65 | 11, 13 |
| 12 | 15 | 10 | | 5 | 8 | 5.3 | 1150 | 380 | 62 | 11, 13 |
| 13 | 20 | | | 5 | 10 | 4.7 | 1060 | 360 | 80 | 11, 13 |
| 14 | 20 | | | 10 | 10 | 4.8 | 1110 | 360 | 75 | 11, 13 |
| 15 | 25 | | | 5 | 10 | 5.0 | 1150 | 370 | 80 | 11, 13 |
| 16 | 15 | 5 | | 5 | 5 | 5.0 | 1060 | 360 | 63 | 12, 13 (FIG. 1) |
| 17 | 20 | 5 | | 5 | 5 | 5.1 | 1100 | 360 | 65 | 12, 13 (FIG. 2) |
| 18 | 25 | 5 | | 5 | 5 | 5.3 | 1150 | 370 | 67 | 12, 13 |
| 19 | 30 | 5 | | 5 | 5 | 5.4 | 1150 | 380 | 67 | 12, 13 |

What is claimed is:

1. A titanium alloy having a composition represented by the chemical formula Ti₁₀₀₋ₓM1ₓ, wherein M1 is at least one element selected from the group consisting of Zr, Hf, Nb, Ta and V, x is atomic % or the sum of atomic % of the element(s), and x is 20 to 80 atomic %.

2. A titanium alloy as claimed in claim 1, wherein x is 20 to 50 atomic %.

3. A titanium alloy as claimed in claim 1, wherein the density of the titanium alloy is equal to or less than 1.5 times that of pure titanium metal.

4. A titanium alloy as claimed in claim 1, wherein the density of the titanium alloy is equal to or less than 1.2 times that of pure titanium metal.

5. A titanium alloy as claimed in claim 1, wherein the tensile strength before cold working is defined to be 500 to 800 MPa.

6. A titanium alloy material obtained by cold working of the titanium alloy claimed in claim 1.

7. A titanium alloy material as claimed in claim 6, wherein the reduction ratio of sectional area during the cold working is defined to be 50 to 95%.

8. A titanium alloy material as claimed in claim 6, wherein the titanium alloy is treated by aging heat treatment after the cold working.

9. A titanium alloy material as claimed in claim 8, wherein the temperature of the aging heat treatment is defined to be 300 to 800° C.

10. A titanium alloy having a composition represented by the chemical formula Ti_{100-x-y}M1ₓM2_{y}, wherein M1 is at least one element selected from the group consisting of Zr, Hf, Nb, Ta and V, x is atomic % or the sum of atomic % of the element(s), M2 is at least one element selected from the group consisting of Al, Sn, Mo, Cr, Ag, Au, Pd, Pt, Ni, Co, Fe, Si, Mn, B, Mm, Sc, Y, La, Ce, Pr, Nd and Sm, y is atomic % or the sum of atomic % of the element(s), and the sum of x and y is 20 to 80 atomic %.

11. A titanium alloy as claimed in claim 10, wherein y is 0.1 to 10 atomic %.

12. A titanium alloy as claimed in claim 10, wherein y is 1 to 5 atomic %.

13. A titanium alloy as claimed in claim 10, wherein the sum of x and y is 20 to 50 atomic %.

14. A titanium alloy as claimed in claim 10, wherein the density of the titanium alloy is equal to or less than 1.5 times that of pure titanium metal.

15. A titanium alloy as claimed in claim 10, wherein the density of the titanium alloy is equal to or less than 1.2 times that of pure titanium metal.

16. A titanium alloy as claimed in claim 10, wherein the tensile strength before cold working is defined to be 500 to 800 MPa.

17. A titanium alloy material obtained by cold working of the titanium alloy claimed in claim 10.

18. A titanium alloy material as claimed in claim 17, wherein the reduction ratio of sectional area during the cold working is defined to be 50 to 95%.

19. A titanium alloy material as claimed in claim 17, wherein the titanium alloy is treated by aging heat treatment after the cold working.

20. A titanium alloy material as claimed in claim 19, wherein the temperature of the aging heat treatment is defined to be 300 to 800° C.
